(19) United States
(12) Patent Application Publication
(10) Pub. No.: US 2026/0273460 A1
(43) Pub. Date: Sep. 17, 2026

(54) SYSTEM FOR PROCESSING GAS AND METHOD FOR PROCESSING GAS USING THE SAME

(71) Applicant: SAMSUNG ELECTRONICS CO., LTD., Suwon-si (KR)

(72) Inventors: Jeong-Yeon SONG, Seoul (KR); Ho Seok PARK, Seoul (KR); Hongdae LEE, Seoul (KR)

(73) Assignees: SAMSUNG ELECTRONICS CO., LTD., Suwon-si (KR); Research & Business Foundation SUNGKYUNKWAN UNIVERSITY, Suwon-si (KR)

(21) Appl. No.: 19/533,648

(22) Filed: Feb. 9, 2026

(30) Foreign Application Priority Data
Mar. 13, 2025 (KR) 10-2025-0032524

(51) Int. Cl. B01D 53/32; B01D 53/70; B01D 53/02

(52) U.S. Cl. CPC B01D 53/326; B01D 53/70; B01D 53/02; B01D 2255/1021; B01D 2255/702; B01D 2255/806; B01D 2257/2066; B01D 2258/0216

(57) ABSTRACT

A gas processing system includes a reaction container for receiving CF₄ gas, a cover covering an upper end of the reaction container, a first electrode passing through the cover and extending into the reaction container, a second electrode passing through the cover and extending into the reaction container and disposed at one side of the first electrode, a third electrode passing through the cover and extending into the reaction container, and interposed between the first and second electrodes, and an electrolyte solution disposed in the reaction container to dissolve the gas.

### CROSS-REFERENCE TO RELATED APPLICATIONS

This application claims priority under 35 U.S.C. § 119 to Korean Patent Application No. 10-2025-0032524 filed on Mar. 13, 2025, in the Korean Intellectual Property Office, the disclosures of which are incorporated by reference herein in their entireties.

### BACKGROUND

Embodiments of the present disclosure described herein relate to a system for processing gas and a method for processing gas using the same.

Semiconductor devices may be fabricated through various semiconductor fabricating processes. In the semiconductor fabricating process, waste gas may be exhausted. The waste gas may include fluorine-based gas and other reaction byproducts. The waste gas may exert harmful effects on the environment and human health when discharged directly, because the waste gas has higher chemical stability and the long-term atmospheric persistence. In this case, the gas processing system may be employed in the process of removing the waste gas. The gas processing system may decompose a toxic ingredient in the waste gas chemically or physically.

Meanwhile, the gas processing system may cause the issues such as environment pollution, higher operating costs, and/or the lower stability in the long-term use. Accordingly, there is required for developing a technology of processing the waste gas in more eco-friendly and cost-effective manners.

### SUMMARY

Embodiments of the present disclosure provide a system for processing gas, capable of reducing environmental pollution, and a method for processing gas using the same.

Embodiments of the present disclosure provide a system for processing gas, capable of improving stability and cost effectiveness, and a method for processing gas using the same.

According to an embodiment, a gas processing system includes a reaction container for receiving CF₄ gas, a cover covering an upper end of the reaction container, a first electrode passing through the cover and extending into the reaction container, a second electrode passing through the cover and extending into the reaction container and disposed at one side of the first electrode, a third electrode passing through the cover and extending into the reaction container, and interposed between the first and second electrodes, and an electrolyte solution disposed in the reaction container to dissolve the gas.

According to an embodiment, a system for processing a gas may include a semiconductor fabricating device to perform a semiconductor fabricating process, a gas processing module disposed at one side of the semiconductor fabricating device, a gas supply unit connected to the semiconductor fabricating device to supply gas produced in the semiconductor fabricating process to the gas processing module, and a gas discharge unit connected to the gas processing module for receiving gas, which is processed, from the gas processing module and discharging the gas to an outside, in which the gas processing module includes a reaction container to receive the gas, a cover covering an upper end of the reaction container, a first electrode passing through the cover and extending into the reaction container, a second electrode passing through the cover, extending into the reaction container, and disposed at one side of the first electrode, a third electrode passing through the cover, extending into the reaction container, and interposed between the first electrode and the second electrode, and an electrolyte solution disposed in the reaction container to dissolve the gas.

According to an embodiment, a method for processing gas using a gas processing system, includes supplying CF₄ gas into a reaction container of a gas processing module, applying a working voltage to a first electrode of the gas processing module, performing an oxidation reaction of an electrolyte solution by forming a potential difference between a second electrode and the electrolyte solution of the gas processing module, performing a reduction reaction of the gas by transferring an electron emitted through the oxidation reaction to the first electrode through the second electrode, and discharging byproduct gas (GB), which is produced through the reduction reaction, out of the gas processing system.

### BRIEF DESCRIPTION OF THE FIGURES

The above and other objects and features of the present disclosure will become apparent by describing in detail embodiments thereof with reference to the accompanying drawings.

FIG. 1 is a perspective view illustrating a system for processing gas, according to an embodiment of the present disclosure.

FIG. 2 is a perspective view illustrating a system for processing gas, according to an embodiment of the present disclosure.

FIG. 3 is a perspective view illustrating a system for processing gas, according to an embodiment of the present disclosure.

FIG. 4 is a flowchart illustrating a method for processing gas using a system for processing gas, according to an embodiment of the present disclosure.

FIGS. 5 and 6 are perspective views illustrating a method for processing gas using a system for processing gas, according to an embodiment of the present disclosure.

FIG. 7 is a graph illustrating the potential difference between a first electrode and a third electrode of a system for processing gas, according to an embodiment of the present disclosure.

FIG. 8 is a view to compare a system for processing gas, according to an embodiment of the present disclosure.

### DETAILED DESCRIPTION

Hereinafter, embodiments of the present disclosure will be described in more detail with reference to accompanying drawings.

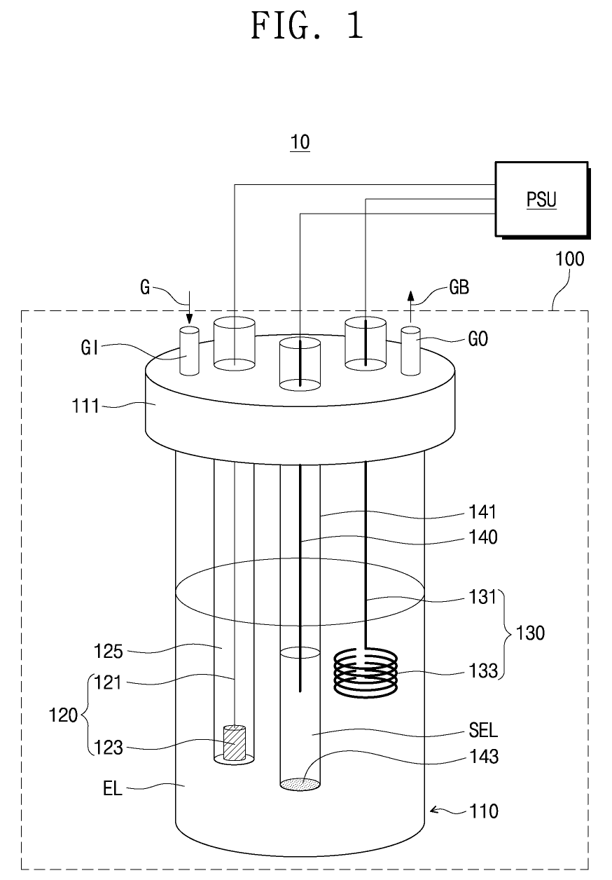

FIG. 1 is a perspective view illustrating a system for processing gas, according to an embodiment of the present disclosure.

Referring to FIG. 1, a gas processing system 10 for processing gas according to an embodiment of the present disclosure may include a reaction container 110, a cover 111, a first electrode 120, a second electrode 130, a third electrode 140, an electrolyte solution EL, and a power controller PUS.

In more detail, the gas processing system 10 according to an embodiment of the present disclosure may be a gas decomposing system to decompose greenhouse gases emitted in various industrial sites. According to an embodiment, the gas processing system 10 may be a gas decomposing system to decompose waste gas emitted in a semiconductor fabricating process. Hereinafter, the details of the gas processing system 10 will be described, and a method for processing gas using the gas processing system 10 will be described thereafter.

The reaction container 110 may provide a space for processing gas in the gas processing system 10. In other words, the reaction container 110 may serve as a reactor to decompose gas. For example, a decomposing reaction of gas G may be made in an inner space of the reaction container 110.

According to an embodiment, the gas G may be emitted in various industrial sites. For example, the gas G may be a waste gas emitted in the semiconductor fabricating process. For example, the gas G may include methane (CH₄), carbon tetrafluoride (CF₄), nitrous oxide (N₂O), hydrofluorocarbon (HFCs), perfluorocarbons (PFCs), carbon dioxide (CO₂), or methane (CH₄). For example, the gas G may be carbon tetrafluoride (CF₄) emitted in the semiconductor fabricating process.

The reaction container 110 may have a cell structure in a cylinder shape having an upper portion open. For example, the reaction container 110 may have a structure extending in a vertical direction and having a cylindrical shape when viewed in a plan view. However, the shape of the reaction container 110 is not limited thereto. For example, the reaction container 110 may have various shapes. For example, the reaction container 110 may have the shape of a square column having an upper portion open.

The cover 111 may be provided to an upper end of the reaction container 110. In other words, the cover 111 may cover the upper end of the reaction container 110. The cover 111 may seal the upper end of the reaction container 110. For example, the cover 111 may serve as a lid of the reaction container 110.

According to an embodiment, a gas inlet nozzle GI and a gas outlet nozzle GO may be provided on a top surface of the cover 111. Each of the gas inlet nozzle GI and the gas outlet nozzle GO may be provided on the cover 111. Each of the gas inlet nozzle GI and the gas outlet nozzle GO may pass through the cover 111 in the vertical direction. In other words, each of the gas inlet nozzle GI and the gas outlet nozzle GO may be provided in the form of a chimney on the cover 111.

The gas inlet nozzle GI may introduce the gas G, which is present outside the reaction container 110, into the reaction container 110. In other words, the gas inlet nozzle GI may serve as a passage to introduce the gas G into the reaction container 110. In addition, the gas inlet nozzle GI may have a structure which is able to be open and close. Accordingly, the gas inlet nozzle GI may control the introduction state of the gas G.

The gas outlet nozzle GO may be disposed at one side of the gas inlet nozzle GI. The gas outlet nozzle GO may discharge byproduct gas GB, which is produced as the gas G is decomposed in the reaction container 110, out of the reaction container 110. In other words, the gas outlet nozzle GO may serve as a passage to discharge the byproduct gas GB out of the reaction container 110. In addition, the gas outlet nozzle GO may have a structure which is able to be open and close. Accordingly, the gas outlet nozzle GO may adjust the discharge of the byproduct gas GB.

An electrolyte solution EL may be provided in the reaction container 110. The gas G may be present in a dissolved state in the electrolyte solution EL. The electrolyte solution EL may serve as a medium to conduct ions such that the gas G is smoothly decomposed.

According to an embodiment of the present disclosure, the electrolyte solution EL may include an organic solvent and an electrolyte salt. In this case, the electrolyte solution EL may include a liquid electrolyte. In other words, the electrolyte solution EL may be formed as the electrolyte salt is dissolved in the organic solvent. The organic solvent may include a compound including carbon (C). For example, the organic solvent may include acetonitrile (ACN), N,N-dimethylformamide (DMF), dimethyl sulfoxide (DMSO), ethylene carbonate (EC), propylene carbonate (PC), tetrahydrofuran (THF), 1,2-dimethoxyethane (DME), dimethyl carbonate (DMC), diethyl carbonate (DEC), ethylmethyl carbonate (EMC), dichloromethane (DCM), hexamethylphosphoric triamide (HMPA), N-Methyl-2-pyrrolidinone (NMP), sulfolane (S), nitromethane, γ-Butyrolactone (GBL), 1,3-dioxolane (DOL), diethyl ether (DEE), methyl formate (MF), methyl propionate (MP), or any combination thereof.

The electrolyte salt may include a cationic salt and an anionic salt. For example, the electrolyte salt may be dissociated into a cation or an anion in the organic solvent. For example, the electrolyte salt may move in the state of a cation or an anion in the organic solvent. Through the movement of the electrolyte salt, the decomposing reaction of the gas G may be promoted. The cation salt may include, for example, tetrabutylammonium (TBA), tetraethylammonium (TEA), or a combination thereof. The anion salt may include tetrafluoroborate (BF₄), hexafluorophosphate (PF₆), perchlorate (ClO₄), bis(trifluoromethanesulfonyl)imide (TFSI), hexafluoroarsenate (AsF₆), trifluoromethanesulfonate (CF₃SO₃), nonafluorobutanesulfonate (C₄F₉SO₃), tetraphenylborate (BPh₄), or any combination thereof.

Alternatively, the electrolyte solution EL may include another type of electrolyte. For example, the electrolyte solution EL may include an ionic liquid electrolyte or a gel electrolyte. The ionic liquid electrolyte may include cation ions and anions ions in a liquid phase. For example, the cation ion may include 1-butyl-3-methylimidazolium (BMIM), 1-ethyl-3-methylimidazolium (EMIM), 1-hexyl-3-methylimidazolium (HMIM), 1-methylimidazolium (MIM), or imidazolium-based cations including a combination thereof, pyridinium-based cations including 1-methylpyridine (MPY), 1-butylpyridine (BPY), or a combination thereof, trialkylammonium-based cations including triethylammonium (TEA), trimethylammonium (TMA), or a combination thereof, and trialkylsulfonium-based cations, aryl-based cations including benzoyl ions (BzIM), or a combination thereof. For example, the anion may include hexafluorophosphate (PF₆⁻), tetrafluoroborate (BF₄⁻), bistrifluoromethanesulfonimide (Tf₂N⁻), chloride (Cl⁻), hexafluoroantimony (SbF₆⁻), trifluoromethanesulfone (TfO⁻), acetylacetone (AcAc⁻), or a combination thereof.

In addition, the gel electrolyte may include a polymer, an organic solvent, and an electrolyte salt. In this case, the organic solvent and the electrolyte salt may include a material substantially the same as the material of the liquid electrolyte. The polymer may include, for example, polyvinyl chloride (PVC), polyvinylidene fluoride (PVDF), polyethylene oxide (PEO), polyacrylic acid (PAA), polymethyl methacrylate (PMMA), nylon, polyvinyl alcohol (PVA), or a combination thereof.

The first electrode 120 may pass through the cover 111. The first electrode 120 may extend into the reaction container 110. In other words, the first electrode 120 may pass through the cover 111 in the vertical direction and extend into the reaction container 110.

The first electrode 120 may serve as a working electrode in the gas processing system 10. In more detail, when the gas processing system 10 operates, the first electrode 120 may provide electrons to the gas G. Accordingly, the first electrode 120 may induce a reduction reaction of the gas G.

According to an embodiment, the first electrode 120 may include a first part 121 and a second part 123. The first part 121 may be an upper end portion of the first electrode 120. The second part 123 may be a lower end portion of the first electrode 120. In other words, the second part 123 may be connected to a lower end of the first part 121. For example, the first part 121 may be a conductive line extending in the vertical direction. The second part 123 may be a metal mass having a diameter larger than a diameter of the first part 121. For example, the first electrode 120 may include platinum (Pt), carbon (C), gold (Au), silver (Ag), palladium (Pd), nickel (Ni), boron-doped diamond (BDD), copper (Cu), iron (Fe), lead (Pb), stainless steel (SUS), titanium (Ti), bismuth (Bi), aluminum (Al), zinc (Zn), or any combination thereof. The second part 123 may include a metal material having reactivity lower than reactivity of the first part 121. For example, the first part 121 may include copper (Cu), and the second part 123 may include platinum (Pt). Accordingly, the second part 123 may serve as an electrocatalyst for the reduction reaction of the gas G in the gas processing system 10.

According to an embodiment, the first electrode 120 may include a material having electrochemical reactivity higher than electrochemical reactivity of the gas G. For example, the first electrode 120 may include a metal material. For example, the first electrode 120 may include a carbon-based electrode, a metal and alloy electrode, a metal oxide and composite electrode, or a modified electrode having reduction reaction activity to the gas G.

The carbon-based electrode may include a glassy carbon electrode (GCE), a graphite electrode, a carbon paste electrode (CPE), carbon nanotubes, CNTs, a graphene electrode, a porous carbon electrode, a boron-doped diamond (BDD), or a pyrolytic carbon electrode.

The metal and alloy electrode may include a precious metal electrode including ruthenium (Ru), rhodium (Rh), palladium (Pd), silver (Ag), gold (Au), platinum (Pt) electrodes, or a combination thereof, a transition metal electrode including scandium (Sc), yttrium (Y), titanium (Ti), vanadium (V), niobium (Nb), tantalum (Ta), chromium (Cr), manganese (Mn), iron (Fe), cobalt (Co), nickel (Ni), copper (Cu), tungsten (W) electrodes, or a combination thereof, a general metal electrode including lead (Pb), bismuth (Bi), aluminum (Al), zinc (Zn) electrodes, or a combination thereof, and an alloy electrode, such as Ni-Fe, Co-Cu, Pd-Au, and steel use stainless steel (SUS).

The metal oxide and composite electrode may include a transition metal oxide-based electrode, such as titanium dioxide (TiO₂), ruthenium dioxide (RuO₂), manganese dioxide (MnO₂), cobalt (II, III) oxide (Co₃O₄), tungsten trioxide (WO₃), or a combination thereof, or an indium tin oxide (ITO) electrode.

According to an embodiment, the modified electrode may be an electrode formed by coating a nano-particle, enzyme, a DNA, or a polymer film on a metal material.

According to an embodiment, an insulator 125 may surround a side surface of the first electrode 120. Accordingly, the insulator 125 and the first electrode 120 may constitute a first electrode structure ES1. The insulator 125 may insulate the electrolyte solution EL from the outer surface of the first electrode 120.

The insulator 125 may include an insulating material. The insulator 125 may include a material which is not deformed in an electrolyte environment and exhibits an excellent chemical resistance. For example, the insulator 125 may include polytetrafluoroethylene (PTFE), polyvinylidene fluoride, perfluoroalkoxy (PFA), ethylene chlorotrifluoroethylene (ECTFE), alumina (Al₂O₃), silica (SiO₂), zirconia (ZrO₂), polyether ether ketone (PEEK), polyimide (PI), polycarbonate (PC), ethylene propylene diene monomer (EPDM), or a combination thereof.

The second electrode 130 may pass through the cover 111. The second electrode 130 may extend into the reaction container 110. In other words, the second electrode 130 may pass through the cover 111 in the vertical direction and extend into the reaction container 110. The second electrode 130 may be disposed at one side of the first electrode 120. In other words, the second electrode 130 may be spaced apart from the first electrode 120.

The second electrode 130 may serve as a counter electrode in the gas decomposing system 10. More specifically, when the gas decomposing system 10 operates, the second electrode 130 may induce an oxidation reaction of the electrolyte solution EL. In other words, the second electrode 130 may receive electrons from the electrolyte solution EL.

According to an embodiment, the second electrode 130 may include a vertical part 131 and a coil part 133. The vertical part 131 may be an upper end portion of the second electrode 130. The coil part 133 may be a lower end portion of the second electrode 130. In other words, the coil part 133 may be connected to a lower end of the vertical part 131. For example, the vertical part 131 may have the shape of a rod extending in the vertical direction. The coil part 133 may have a coil shape having a surface area larger than a surface area of the vertical part 131. According to an embodiment, the vertical part 131 and the coil part 133 may be integrally connected to each other.

According to an embodiment, the second electrode 130 may include a material having excellent electrochemical stability, oxidation durability, and/or electrical conductivity. For example, the second electrode 130 may include platinum (Pt), gold (Au), nickel (Ni), carbon (C), or a combination thereof. According to an embodiment, the second electrode 130 may include substantially the same material as the second part 123 of the first electrode 120. For example, the second electrode 130 and the second part 123 of the first electrode 120 may include platinum (Pt).

According to an embodiment, the second electrode 130 may include inactive metal, a transition metal oxide, a carbon-based electrode, a reference electrode, or a combination thereof. The inert metal may include gold (Au), palladium (Pd), titanium (Ti), or a combination thereof. The transition metal oxide may include a transition metal-based oxide electrode composed of nickel (Ni), cobalt (Co), manganese (Mn), or a combination thereof. The carbon-based electrode may include an electrode consisting of glassy carbon electrode (GCE), graphite, carbon cloth, carbon paper, carbon nanotubes (CNT), graphene, or a combination thereof. The reference electrode may include a silver/silver chloride (Ag/AgCl) electrode.

According to an embodiment, a contact area between the second electrode 130 and the electrolyte solution EL may be designed to be larger than a contact area between the first electrode 120 and the electrolyte solution EL. For example, the second electrode 130 may include the coil part 133 to increase the contact area with the electrolyte solution EL.

According to an embodiment, the second electrode 130 may constitute a second electrode structure ES2. In this structure, the second electrode structure ES2 may be substantially the same as the second electrode 130. However, the structure and the shape of the second electrode structure ES2 are provided only for the illustrative purpose. The second electrode structure ES2 may have various structures and various shapes. For example, the second electrode structure ES2 may further include an additional component provided on the surface of the second electrode 130. For example, the side surface of the second electrode 130 may be coated with an additional insulating material. In this case, the second electrode 130 and the coated insulating material may form the second electrode structure ES2.

The third electrode 140 may pass through the cover 111. The third electrode 140 may extend into the reaction container 110. In other words, the third electrode 140 may pass through the cover 111 in the vertical direction and extend into the reaction container 110. The third electrode 140 may be disposed at one side of the first electrode 120. The third electrode 140 may be disposed at one side of the second electrode 130. In other words, the second electrode 130 may be disposed between the first and second electrodes 120 and 130.

The third electrode 140 may serve as a reference electrode in the gas decomposing system 10. More specifically, when the gas decomposing system 10 operates, a reference voltage may be applied to the third electrode 140, and an oxidation-reduction reaction may not be made on the third electrode 140. Accordingly, the third electrode 140 may serve as a reference point for stably measuring and maintaining the potential of the first electrode 120 in the gas decomposing system 10. In other words, the third electrode 140 may provide a reference potential for controlling the potential of the gas decomposing system 10.

According to an embodiment, the third electrode 140 may include a material having excellent electrochemical stability, excellent oxidation durability, and/or excellent electrical conductivity. For example, the third electrode 140 may include silver (Ag).

According to an embodiment, the third electrode 140 may include various materials. For example, the third electrode 140 may include mercury (Hg), platinum (Pt), palladium (Pd), or a combination thereof.

According to an embodiment, a cylinder 141 may receive the third electrode 140. In other words, the third electrode 140 may be provided in the cylinder 141. The cylinder 141 may pass through the cover 111. The cylinder 141 may extend into the reaction container 110. In other words, the cylinder 141 having the third electrode 140 received therein may pass through the cover 111 in the vertical direction to extend into the reaction container 110. The cylinder 141 may have a cylinder shape.

According to an embodiment, a reference electrolyte solution SEL may be provided in the cylinder 141. A level of a top surface of the reference electrolyte solution SEL may be higher than a level of a lowermost end of the third electrode 140. According to an embodiment, the reference electrolyte solution SEL may include substantially the same material as the electrolyte solution EL provided in the reaction container 110.

According to an embodiment, a separator 143 may be provided on a bottom surface of the cylinder 141. In other words, the separator 143 may be mounted on the bottom surface of the cylinder 141. The separator 143 may separate the electrolyte solution EL, which is provided in the reaction container 110, from the third electrode 140 in the cylinder 141. In addition, the separator 143 may prevent the electrolyte solution EL, which is provided in the reaction container 110, from being mixed with the reference electrolyte solution SEL which is provided in the cylinder 141. Accordingly, the separator 143 may perform a role of maintaining the performance of the third electrode 140 in the gas decomposing system 10.

The separator 143 may have, for example, a porous structure. The separator 143 may include, for example, alumina (Al₂O₃), zirconia (ZrO₂), Nafion, or a combination thereof. According to an embodiment of the present disclosure, the third electrode 140, the cylinder 141, the separator 143, and the reference electrolyte solution SEL may constitute the third electrode structure ES3.

According to an embodiment, when the third electrode 140 includes mercury (Hg), the third electrode structure ES3 may be a saturated calomel electrode (SCE). When the third electrode 140 includes platinum (Pt), the third electrode structure ES3 may be a standard hydrogen electrode (SHE). When the third electrode 140 includes palladium (Pd), the third electrode structure ES3 may be a palladium hydride electrode.

According to an embodiment, a level of a top surface of the electrolyte solution EL may be higher than levels of lowermost ends of the first, second, and third electrodes 120, 130, and 140. For example, the level of the top surface of the electrolyte solution EL may be higher than the level of the lowermost end of the first electrode 120. For example, the level of the top surface of the electrolyte solution EL may be higher than the level of the lowermost end of the second electrode 130. For example, the level of the top surface of the electrolyte solution EL may be higher than the level of the lowermost end of the third electrode 140.

According to an embodiment, the reaction container 110, the cover 111, the first, second, and third electrodes 120, 130, and 140, the electrolyte solution EL may constitute one gas processing module 100. For example, the gas G may be introduced into the reaction container 110 of the gas processing module 100 through the gas inlet nozzle GI. The gas introduced into the reaction container 110 may be dissolved in the electrolyte solution EL. As the gas G dissolved in the electrolyte solution EL receives electrons from the first electrode 120 and reduced, the byproduct gas GB may be produced. The byproduct gas GB may be discharged out of the gas processing module 100 through the gas outlet nozzle GO. The gas processing module 100 may decompose the gas through the above-described processes.

A power controller PSU may be provided at one side of the gas processing module 100. The power controller PUS may be connected to the first, second, and third electrodes 120, 130, and 140. The power controller PUS may be connected to upper end portions of the first, second, and third electrodes 120, 130, and 140 through separate wirings.

The power controller PUS may apply a voltage to the first electrode 120. The power controller PUS may apply a working voltage to the first electrode 120. Accordingly, the power controller PUS may induce the reduction reaction of the gas G in the first electrode 120. In addition, the power controller PUS may apply a voltage to the third electrode 140. For example, the power controller PUS may apply a reference voltage to the third electrode 140. In this case, the reference voltage may be a voltage corresponding to a standard reduction potential value of the third electrode 140.

The power controller PUS may uniformly maintain the potential difference between the first electrode 120 and the third electrode 140 at a substantially constant level. More specifically, when a value corresponding to the potential difference set is input into the power controller PUS, the power controller PUS may apply a working voltage, which has an intensity corresponding to the relevant potential difference, to the first electrode 120. During this process, the power controller PUS may control a quantity of a current flowing through the second electrode 130 to maintain the potential of the first electrode 120 to a set value.

Accordingly, the power controller PUS may uniformly maintain the potential difference between the first electrode 120 and the third electrode 140 at a substantially constant level, such that the gas decomposing reaction is stably performed. As used herein, the expression “potential difference being maintained at a substantially constant level” may refer to having a relatively uniform potential difference between the two electrodes, rather than having a varying potential difference, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ± 1%, ± 5% , or ± 10% of the actual value stated, and other suitable tolerances.

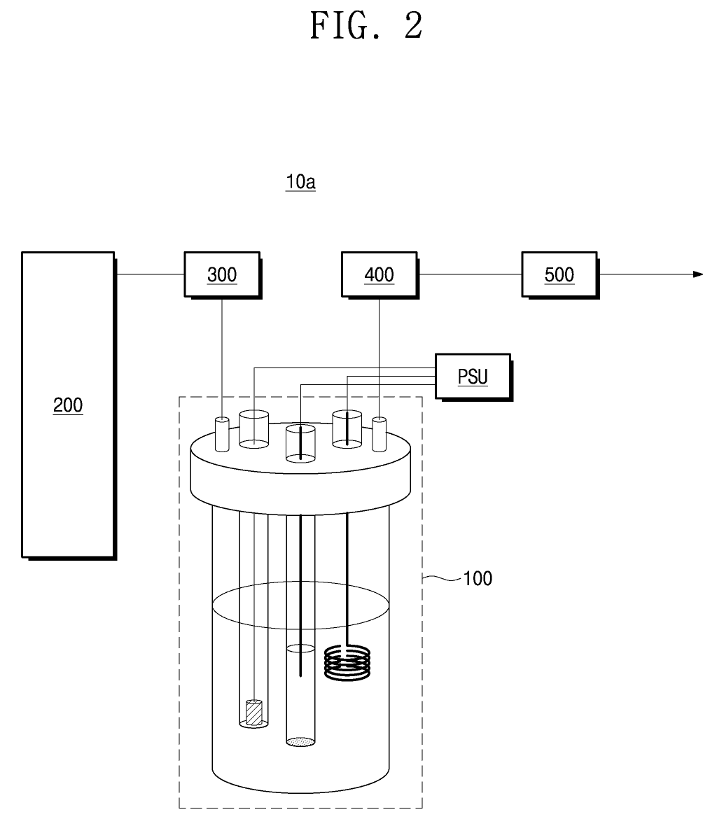

FIG. 2 is a perspective view illustrating a system for processing gas, according to an embodiment of the present disclosure.

Referring to FIG. 2, according to an embodiment of the present disclosure, a gas processing system 10a may include a semiconductor fabricating device 200, a gas supply unit 300, a post-treatment device 400, and a gas discharge unit 500.

The semiconductor fabricating device 200 may be an equipment to perform a semiconductor fabricating process. For example, the semiconductor fabricating device 200 may be etching equipment, deposition equipment, cleaning equipment, exposure equipment, or transfer equipment. However, the semiconductor fabricating device 200 is not limited to the above example. For example, the semiconductor fabricating device 200 may include various types of equipment to perform the semiconductor fabricating process.

The gas supply unit 300 may be provided at one side of the semiconductor fabricating device 200. The gas supply unit 300 may be interposed between the semiconductor fabricating device 200 and the gas processing module 100. The gas supply unit 300 may be connected to the semiconductor fabricating device 200 and the gas processing module 100 through additional pipes. The gas supply unit 300 may store the gas G produced from the semiconductor fabricating device 200. The gas supply unit 300 may provide the stored gas G into the gas processing module 100. For example, the gas supply unit 300 may supply the gas G through the gas inlet nozzle GI (see FIG. 1) to inject the gas G into the reaction container 110 (see FIG. 1).

The post-treatment device 400 may be provided at one side of the gas processing module 100. The post-treatment device 400 may be interposed between the gas processing module 100 and the gas discharge unit 500. The post-treatment device 400 may be connected to the gas processing module 100 and the gas discharge unit 500 through additional pipes. The post-treatment device 400 may treat the byproduct gas GB decomposed through the gas processing module 100. The post-treatment device 400 may post-treat the byproduct gas GB and may supply the post-treated gas to the gas discharge unit 500.

More specifically, the post-treatment device 400 may change the byproduct gas GB, which is decomposed in the gas processing module 100, to be in a stable state. Accordingly, the post-treatment device 400 may remove byproducts of the gas G processed by the gas processing module 100. To this end, the post-treatment device 400 may purify the byproduct gas GB through a specific chemical, physical, or catalytic manner.

The post-treatment device 400 may treat the byproduct gas GB through various purifying manners. For example, specific ingredients in the byproduct gas GB may be selectively removed, by including an adsorption device. For example, the byproduct gas GB may be treated using an activated carbon filter or a zeolite-based adsorbent. In addition, the post-treatment device 400 may include a catalyst layer which induces an oxidation reaction, thereby converting reactive gas, which is present in the byproduct gas GB, into a more stable material.

According to an embodiment, the post-treatment device 400 may include a gas cleaning system. The gas cleaning system may operate by removing a soluble ingredient from the byproduct gas by utilizing a liquid absorbent. For example, the post-treatment device 400 may apply a manner of utilizing an alkaline solution to neutralize acidic byproduct gas.

According to an embodiment, the post-treatment device 400 may convert the reactive byproduct to be in a solid phase or a liquid phase. The post-treatment device 400 may precipitate or condense a specific compound to convert the specific compound into a solid and then remove the result through a filtering system.

The gas discharge unit 500 may be provided at one side of the gas processing module 100. The gas discharge unit 500 may be provided at one side of the post-treatment device 400. The gas discharge unit 500 may connected to the post-treatment device 400 through an additional pipe. The gas discharge unit 500 may discharge gas, which is completely post-treated in the post-treatment device 400, out of the gas processing system 10a.

According to an embodiment, the post-treatment device 400 may be omitted. In this case, the gas processing module 100 may be directly connected to the gas discharge unit 500. For example, the byproduct gas discharged from the gas processing module 100 may be introduced into the gas discharge unit 500.

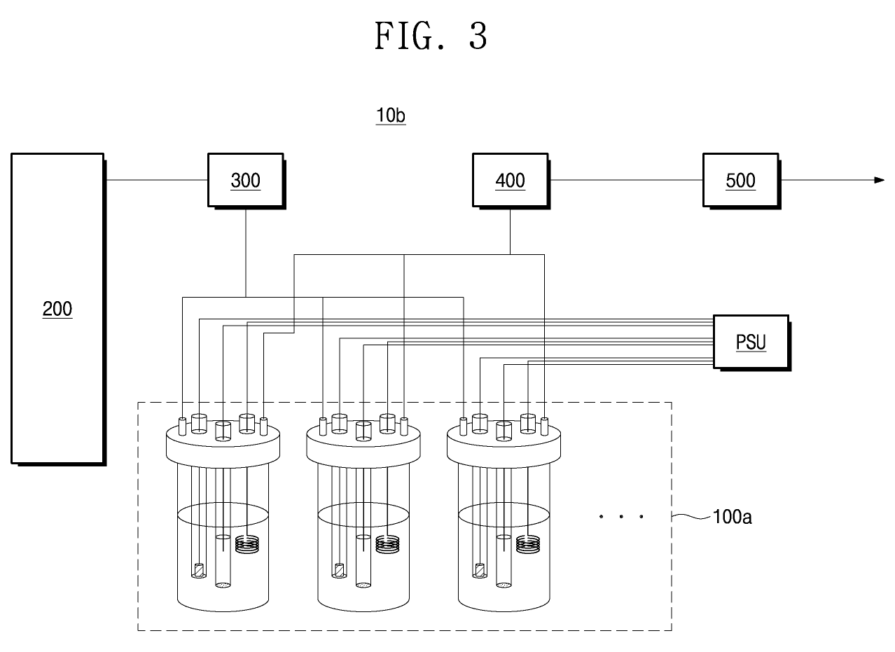

FIG. 3 is a perspective view illustrating a system for processing gas, according to an embodiment of the present disclosure.

Referring to FIG. 3, a gas processing system 10b according to an embodiment of the present disclosure may include a plurality of gas processing modules 100a. For example, the gas processing system 10b may include three gas processing modules 100a. For example, the gas processing system 10b may include 10 gas processing modules 100a. Accordingly, the decomposition rate and the decomposition efficiency of the gas G may be improved.

The gas processing modules 100a may be connected to the power controller PUS. In other words, one power controller PUS may be connected to the plurality of gas processing modules 100a. Accordingly, the power controller PUS may integrally control the gas processing modules 100a.

Meanwhile, hereinafter, the method for processing gas using the gas processing system according to an embodiment of the present disclosure will be described.

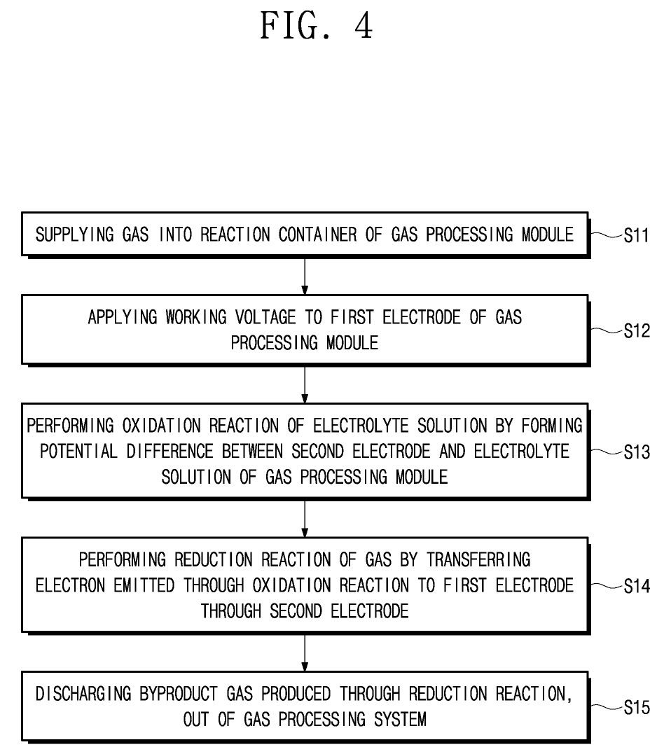

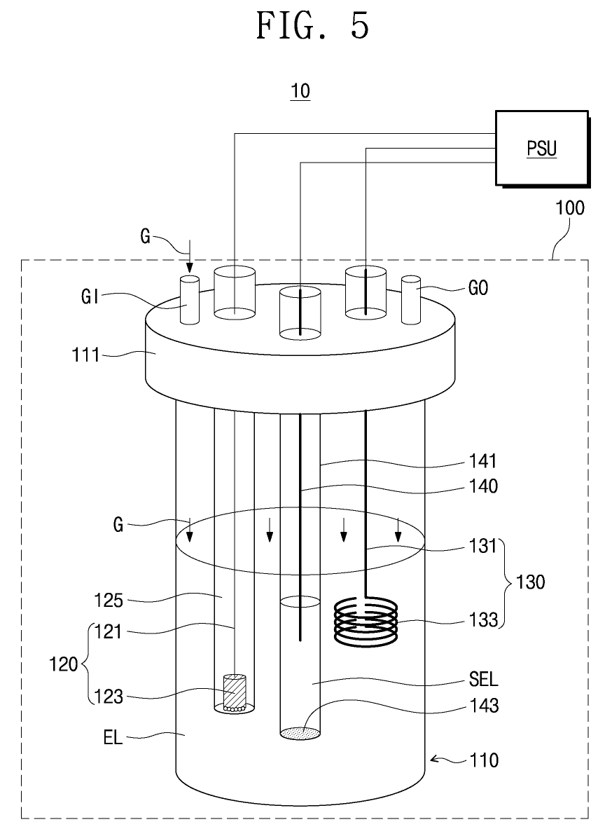

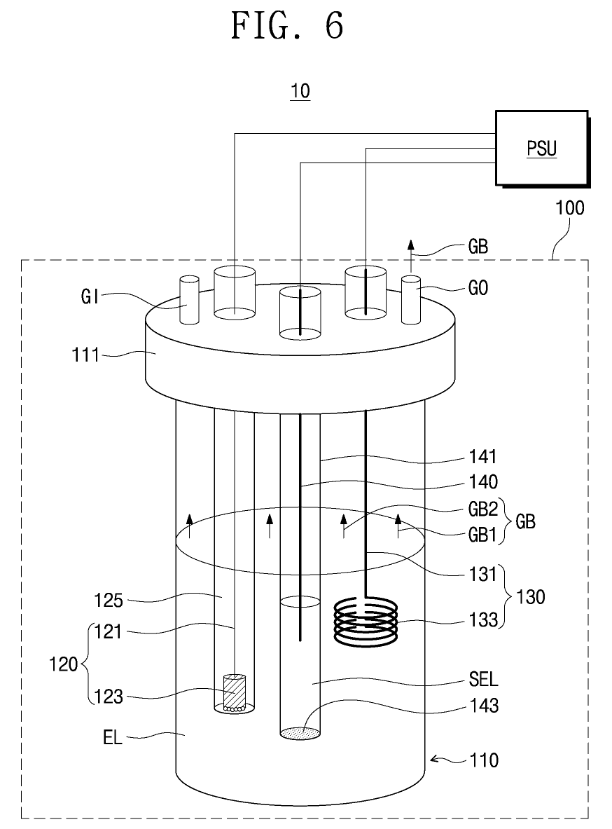

FIG. 4 is a flowchart illustrating the method for processing the gas using the gas processing system, according to an embodiment of the present disclosure. FIGS. 5 and 6 are perspective views illustrating the method for processing the gas using the gas processing system, according to an embodiment of the present disclosure.

Referring to FIGS. 4-6, the method for processing the gas may include supplying CF₄ gas to the reaction container of the gas processing module (S11), applying a working voltage to the first electrode of the gas processing module (S12), forming the potential difference between the second electrode and the electrolyte solution of the gas processing module to perform an oxidation reaction of the electrolyte solution (S13), transferring the electron, which is emitted from the oxidation reaction, to the first electrode through the second electrode to perform a reduction reaction of the gas (S14), and discharging byproduct gas, which is produced through the reduction reaction, out of the gas processing system (S15).

First, the process for supplying the CF₄ gas G into the reaction container 110. The gas G may be supplied through the gas inlet nozzle GI. In this case, the gas G may be dissolved in the electrolyte solution EL of the reaction container 110. To this end, a gas disperser, a stirring device, or a gas diffusion mechanism may be applied. As the gas G is dissolved in the electrolyte solution EL, the reduction reaction of the gas G generated may be accelerated through the first electrode 120.

Next, the working voltage may be applied to the first electrode 120. The working voltage may be applied through the power controller PUS. Accordingly, the reduction reaction of the gas G may be induced. The intensity of the working voltage may be set to be appropriate to performing the electrochemical reduction reaction of the gas G. In this case, the potential of the first electrode 120 may be set based on the potential of the third electrode 140. For example, when the potential difference between the first electrode 120 and the third electrode 140 is applied to the power controller PUS, the power controller PUS may apply the working voltage having the intensity corresponding to the potential difference to the first electrode 120.

The oxidation reaction may be made in the second electrode 130 to smoothly make the reduction reaction of the gas G in the first electrode 120. To this end, the power controller PUS may form the potential difference between the first electrode 120 and the third electrode 140. The power controller PUS may control the potential of the first electrode 120 based on the third electrode 140 such that the set potential difference is maintained. In this process, the voltage applied to the second electrode 130 may be determined based on the potential of the first electrode 120 and the flow of a current in the gas processing system 10. In other words, the voltage of the second electrode 130 may be automatically controlled to a value corresponding to the potential difference set between the first electrode 120 and the third electrode 140. For example, the potential of the first electrode 120 may be set to be lower than the potential of the second electrode 130.

The oxidation reaction of the anion may be performed in the electrolyte solution EL, due to the potential difference between the second electrode 130 and the electrolyte solution EL. The anion may be, for example, PF₆-. Accordingly, the anion may emit electrons, and the emitted electrons may be transferred to the second electrode 130.

Thereafter, the electron may be transferred to the power controller PUS through the second electrode 130, and transferred to the first electrode 120 through the power controller PUS. The gas G may perform the reduction reaction by receiving the electron transferred to the first electrode 120. In this process, the power controller PUS may adjust an amount of electrons transferred to the first electrode 120. Accordingly, the reduction reaction speed of the gas G may be uniformly maintained.

The gas G may be decomposed through the reduction reaction. Accordingly, the byproduct gas GB may be produced. The byproduct gas GB may include at least two types of heterogeneous materials. For example, the byproduct gas GB may include a first byproduct gas GB1 and a second byproduct gas GB2. In other words, the gas G may be reduced by the first electrode 120 and may be decomposed into the first byproduct gas GB1 and the second byproduct gas GB2.

According to an embodiment, the process (decomposing process) for decomposing the gas G may be performed under the conditions of a normal temperature and atmospheric pressure. For example, the decomposing process may be performed at the temperature ranging from 20° C to 50° C. For example, the decomposing process may be performed under the condition ranging from 90 kPa to 110 kPa. In other words, the gas processing system 10 may decompose the gas G under the conditions of the normal temperature and the atmospheric pressure without the additional heat treatment and setting the additional pressure. Accordingly, the gas processing system 10 according to an embodiment of the present disclosure may save energy consumption and improve the cost-effectiveness.

According to an embodiment, the first byproduct gas GB1 and the second byproduct gas GB2 may include at least one of elements included in the gas G. For example, when the gas G is CF₄, the first byproduct gas GB1 may include carbon (C), and the second byproduct gas GB2 may include fluorine (F).

According to an embodiment, the byproduct gas GB present inside the reaction container 110 may be discharged out of the gas processing system 10 through the gas outlet nozzle GO. For example, the byproduct gas GB may be transferred to the post-treatment device 400 through the gas outlet nozzle GO. Thereafter, the byproduct gas GB may be additionally treated in the post-treatment device 400, and then may be discharged out of the gas processing system 10 through the gas outlet nozzle GO.

### Experimental example

Meanwhile, an experimental example of an electrochemical decomposition experiment of CF₄ gas using a gas processing system according to an embodiment of the present disclosure will be described below.

Experimental manner and experiment conditions

The present experiment was performed to examine the electrochemical reduction potential of CF₄, comparing CF₄ with argon (Ar), which is inert gas, using the gas processing system according to an embodiment of the present disclosure, thereby determining the electrochemical behavior. More specifically, whether the reduction reaction of CF₄ was made at a specific voltage was analyzed to examine the possibility of electrochemical processing of CF₄.

Cyclic voltammetry (CV), which is electrochemical analysis equipment, was used as experimental measuring equipment. Accordingly, an environment (experimental group) containing CF₄ was compared with argon (Ar) environment (control group) in terms of an electrochemical reaction.

The experiment was performed using a three-electrode electrode system. The first electrode 120 (see FIG. 1) was employed as a working electrode, the second electrode 130 (see FIG. 1) was used as a counter electrode, and the third electrode 140 (see FIG. 1) was used as a reference electrode. A platinum (Pt) or a glassy carbon (GC) electrode was used as the working electrode, and an Ag/Ag⁺ electrode was used as the reference electrode to relatively measure the potential. A platinum (Pt) electrode was used as the counter electrode.

For the electrolyte, 0.1 M tetrabutylammonium hexafluorophosphate (TBAPF₆) in propylene carbonate (PC) were used. The voltage scan range was set to range from 0 V to -3.0 V, and the voltage scan rate was adjusted to 50 mV/s. The experiment was performed under two gas conditions. One gas condition was an environment in which inert gas (Ar) was injected (control group), and a remaining gas condition was an environment in which CF₄ gas was injected (experimental group). The gas was supplied at a constant flow rate of 10 standard cubic centimeters per minute (sccm), and a constant concentration was maintained during the experiment.

The experiment was performed under the pressure of 1 atm while maintaining the temperature at 25° C (room temperature). The reaction container 110 (see FIG. 1) was used as a container in which the experiment was performed. In this case, an airtight reaction cell was used as the reaction container 110 (see FIG. 1). In addition, the experiment was performed in the state that the gas and the solution were stirred.

### Experimental result

As a result of cyclic voltammetry (CV) measurements, the X-axis indicates Potential (V vs Ag/Ag⁺), and the lower potential (negative direction) causes the stronger reduction reaction. The Y-axis represents a current density (mA/cm²), and refers to an amount of current generated from the electrode per unit area. As the current density increases in the negative direction, many more electrons are supplied from the electrode, such that the reduction reaction is more strongly made.

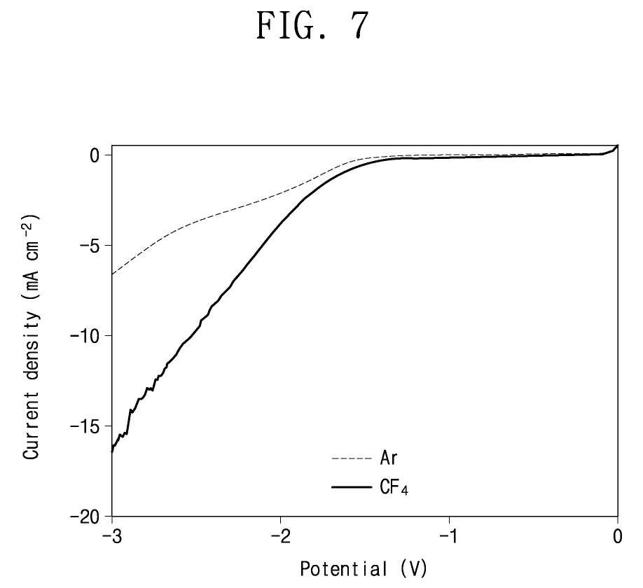

FIG. 7 is a graph illustrating the potential difference between a first electrode and a third electrode according to an embodiment of the present disclosure. In more detail, FIG. 7 is a graph illustrating the measurement result of a cyclic voltammetry (CV) according to the present experiment. Referring to FIG. 7, a current was observed as being sharply increased at -1.5 V or less under the environment (indicated by a black bold line) including CF₄. This refers to that CF₄ is electrochemically reduced at a specific voltage, such that electrons strongly move on the surface of an electrode. Meanwhile, a current was not greatly increased in the same potential region under an Ar (inert gas) environment (dotted line), which indicates that a meaningful reduction reaction was not made under an environment without CF₄.

This difference indicates that CF₄ receives electrons on an electrode surface to make a reduction reaction. In other words, CF₄ may be electrochemically decomposed at the specific potential. Accordingly, it may be recognized that CF₄ may be electrochemically processed under the condition of a normal temperature and atmospheric pressure, using the gas processing system according to an embodiment of the present disclosure.

### Comparative example

Hereinafter, a comparative example of a high-temperature catalytic hydrolysis experiment of CF₄ gas to compare with the gas processing system according to an embodiment of the present disclosure will be described.

Experimental manner and experimental condition

In the present experiment, the decomposition efficiency and limitations of CF₄ gas was evaluated through a high-temperature catalytic hydrolysis manner, which is one of conventional representative manners for decomposing greenhouse gas, to compare with a manner for electrochemically decomposing CF₄ using the gas processing system according to an embodiment of the present disclosure. This was performed to effectively verify whether the conventional high-temperature catalytic hydrolysis manner was effective for processing CF₄, and to analyze the problem in the manner.

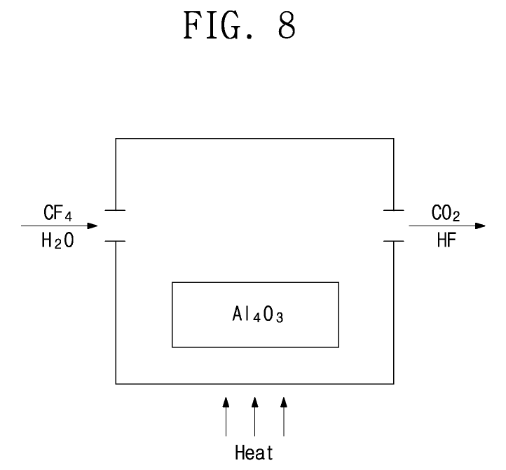

FIG. 8 is a view to compare a system for processing gas, according to an embodiment of the present disclosure. In more detail, FIG. 8 is a view illustrating a thermal catalytic hydrolysis experiment of CF₄ gas. Referring to FIG. 8, in the present experiment, gas including CF₄ was injected into a reactor and the decomposing reaction was induced using high-temperature catalyst through a continuous fixed layer reactor. The continuous fixed layer reactor employed a 3/4 inch Inconel material reactor. As a catalyst, a γ-Al₂O₃ (alumina) or a γ-Al₂O₃ modified with metals such as Zn, Ni, Mg, Sr, and Ba.

The reaction conditions were performed at a high temperature of 750°C, and gas was injected under an atmospheric pressure of 1 atm, thereby performing the experiment. The composition of the injected gas was set to CF₄ (0.7%), H₂O (34.5%), and He (inert gas, balance), and the space velocity (gas hourly space velocity (GHSV) was maintained at 2000 h ⁻¹.

The main target of the experiment is to analyze the rate of decomposition and the reaction product of CF₄ and to identify the byproducts such as CO₂, and HF of the products, to evaluate the degradation of the catalyst. Gas Chromatography was used as analysis equipment, and a water scrubber was applied to remove HF.

### Experimental result

According to the experiment result, 100% of CF₄ was decomposed to show higher reactivity at the initial stage of the experiment. However, after 22 hours, the activation of the catalyst was rapidly reduced. The cause of the experiment result was determined as the degradation of the catalyst and reduction of a specific surface area.

According to the comparison result of the physical property after and before the use of the catalyst, the γ-Al₂O₃ catalyst was phase-transformed into α-Al₂O₃ after a long-term reaction at a high temperature of 750°C, thereby reducing a lower activity of the catalyst. In addition, the specific surface area of the catalyst was sharply reduced from 197.9 m²/g before the experiment to 6.0 m²/g after the experiment. Accordingly, it may be recognized that the active site of the catalyst was sharply reduced.

According to a result of reaction product analysis, CO₂ and HF were detected as major byproducts. In particular, as HF (hydrogen fluoride) was produced, the possibility of corrosion inside the reactor increased, and an additional post-treatment process was required.

### Review

According to the present disclosure, although the high-temperature hydrolysis manner initially showed a high decomposition rate of CF₄, but the performance was rapidly deterioration due to the degradation of catalyst during the long-term operation. This is analyzed as being caused by catalyst poisoning and the structural changes at higher temperature.

In addition, corrosive byproducts, such as HF, were produced during the experiment procedure. This indicates that corrosion problems are caused in the reactor with higher possibility, such that an additional post-treatment process is required. Accordingly, the catalyst manner may incur high operating costs and facility maintenance costs, and may have disadvantages in terms of cost-effectiveness in practical commercialization.

As described above, since the gas processing system 10, 10a, or 10b (see FIGS. 1, 2, or 3) according to an embodiment of the present disclosure is operable, under the conditions of a normal temperature and atmospheric pressure. When compared to the high-temperature catalyst hydrolysis manner, energy consumption and catalyst poisoning problems may be improved. In addition, since HF production is reduced, additional anti-corrosion equipment is not required, thereby providing a simpler system. Accordingly, according to an embodiment of the present disclosure, the gas processing system 10, 10a, or 10b (see FIGS. 1, 2, and 3) may be improved in cost-effectiveness, energy efficiency and processing stability.

According to the present disclosure, in the system for processing gas and the method for processing gas using the same, the environmental pollution may be reduced.

According to the present disclosure, in the system for processing gas and the method for processing gas using the same, the stability and the cost effectiveness may be improved.

Although an embodiment of the present disclosure has been described for illustrative purposes, those skilled in the art will appreciate that various modifications, and substitutions are possible, without departing from the scope and spirit of the invention as disclosed in the accompanying claims.

Accordingly, the technical scope of the present disclosure is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A system for processing a gas, the system comprising:
a reaction container configured to receive CF₄ gas;
a cover covering an upper end of the reaction container;
a first electrode passing through the cover and extending into the reaction container;
a second electrode passing through the cover, extending into the reaction container, and disposed at one side of the first electrode;
a third electrode passing through the cover, extending into the reaction container, and interposed between the first and second electrodes; and
an electrolyte solution disposed in the reaction container and configured to dissolve the gas.

2. The system of claim 1, wherein the first electrode is configured to provide an electron to the gas, and
wherein the second electrode is configured to receive an electron from the electrolyte solution.

3. The system of claim 2, wherein the gas is reduced by the first electrode in a decomposing procedure where the gas is decomposed into a first byproduct gas and a second byproduct gas, and
wherein the first byproduct gas includes carbon, and the second byproduct gas includes fluorine.

4. The system of claim 3, wherein the decomposing procedure is performed under a condition of a temperature ranging from 20℃ to 50℃, and
wherein the decomposing procedure is performed under a condition of pressure ranging from 90 kPa to 110 kPa.

5. The system of claim 1, wherein the first electrode includes a material having electrochemical reactivity higher than electrochemical reactivity of the gas.

6. The system of claim 1, further comprising:
a power controller connected to upper end portions of the first, second, and third electrodes,
wherein the power controller is configured to apply a voltage to the first electrode.

7. The system of claim 6, wherein the power controller is configured to maintain a potential difference between the third electrode and the first electrode at a substantially constant level.

8. The system of claim 1, wherein potential of the first electrode is configured to be lower than potential of the second electrode.

9. The system of claim 1, wherein a level of a top surface of the electrolyte solution is higher than levels of lowest ends of the first, second, and third electrodes.

10. The system of claim 1, further comprising:
an insulator surrounding a side surface of the first electrode;
a cylinder passing through the cover, extending into the reaction container, and configured to receive the third electrode;
a separator disposed on a bottom surface of the cylinder; and
a reference electrolyte solution disposed in the cylinder.

11. The system of claim 1, wherein a lower end portion of the first electrode includes:
platinum (Pt), carbon (C), gold (Au), silver (Ag), palladium (Pd), nickel (Ni), boron-doped diamond (BDD), copper (Cu), iron (Fe), lead (Pb), stainless steel (SUS), titanium (Ti), bismuth (Bi), aluminum (Al), zinc (Zn) ruthenium (Ru), rhodium (Rh), scandium (Sc), yttrium (Y), vanadium (V), niobium (Nb), tantalum (Ta), chromium (Cr), manganese (Mn), cobalt (Co), tungsten (W), glassy carbon, graphite, carbon paste, carbon nanotube (CNT), graphene, porous carbon, pyrolytic carbon, TiO₂, ruthenium dioxide (RuO₂), manganese dioxide (MnO₂), cobalt (II, III) oxide (Co₃O₄), tungsten trioxide (WO₃), indium tin oxide (ITO), or any combination thereof, and
wherein the second electrode includes:
platinum (Pt), gold (Au), palladium (Pd), titanium (Ti), nickel (Ni), cobalt (Co), manganese (Mn), carbon (C), glassy carbon, graphite, carbon cloth, carbon paper, carbon nano tube (CNT), graphene, silver (Ag), or any combination thereof.

12. The system of claim 1, wherein a contact area between the first electrode and the electrolyte solution is smaller than a contact area between the second electrode and the electrolyte solution.

13. The system of claim 1, wherein the third electrode includes:
mercury (Hg), platinum (Pt), palladium (Pd), silver (Ag), or any combination thereof.

14. The system of claim 1, wherein the electrolyte solution includes:
an organic solvent and an electrolyte salt.

15. The system (10) of claim 14, wherein the organic solvent includes:
acetonitrile (ACN), N,N-Dimethylformamide, (DMF), dimethyl sulfoxide (DMSO), ethylene carbonate (EC), propylene carbonate (PC), tetrahydrofuran (THF),1,2-dimethoxyethane, (DME), dimethyl carbonate (DMC), diethyl carbonate (DEC), ethylmethyl carbonate (EMC), dichloromethane (DCM), hexamethylphosphoric triamide (HMPA), N-Methyl-2-pyrrolidinone (NMP), sulfolane (S), ntromethane, γ-Butyrolactone (GBL),1,3-dioxolane (DOL), diethyl ether, (DEE), methyl formate (MF), methyl propionate (MP), or any combination thereof.

16. The system of claim 14, wherein the electrolyte salt includes:
a cationic salt and an anionic salt,
wherein the cationic salt includes:
tetrabutylammonium (TBA), tetraethylammonium (TEA), or any combination thereof, and
wherein the anionic salt includes:
tetrafluoroborate (BF₄), hexafluorophosphate (PF₆), perchlorate (ClO₄), bis(trifluoromethanesulfonyl)imide (TFSI), hexafluoroarsenate (AsF₆), trifluoromethanesulfonate (CF₃SO₃), nonafluorobutanesulfonate (C₄F₉SO₃), tetraphenylborate (BPh₄), or any combination thereof.

17. The system of claim 1, wherein the reaction container, the cover, the first, second, and third electrodes, and the electrolyte solution constitute one gas processing module,
wherein a plurality of gas processing modules are provided, and
wherein the power controller is connected to the plurality of gas processing modules.

18. A system for processing a gas, the system comprising:
a semiconductor fabricating device configured to perform a semiconductor fabricating process;
a gas processing module disposed at one side of the semiconductor fabricating device;
a gas supply unit connected to the semiconductor fabricating device to supply a gas, which is produced in the semiconductor fabricating process, to the gas processing module; and
a gas discharge unit connected to the gas processing module to receive gas, which is processed, from the gas processing module and discharge the gas to an outside,
wherein the gas processing module includes:
a reaction container configured to receive the gas (G);
a cover covering an upper end of the reaction container;
a first electrode passing through the cover and extending into the reaction container;
a second electrode passing through the cover, extending into the reaction container, and disposed at one side of the first electrode ;
a third electrode passing through the cover, extending into the reaction container and interposed between the first electrode and the second electrode ; and
an electrolyte solution disposed in the reaction container and configured to dissolve the gas.

19. The system of claim 18, further comprising:
a post-treatment device connected between the gas discharge unit and the gas processing module, and configured to remove byproducts of the gas produced from the gas processing module.

20. A method for processing gas using a processing gas system, the method comprising:
supplying CF₄ gas into a reaction container of a gas processing module;
applying a working voltage to a first electrode of the gas processing module;
performing an oxidation reaction of an electrolyte solution by forming a potential difference between a second electrode and the electrolyte solution of the gas processing module;
performing a reduction reaction of gas by transferring an electron, which is emitted through the oxidation reaction, to the first electrode through the second electrode; and
discharging byproduct gas, which is produced through the reduction reaction, out of the gas processing system.
